(19) United States
(12) Patent Application Publication
(10) Pub. No.: US 2024/0072000 A1
(43) Pub. Date: Feb. 29, 2024

(54) SEMICONDUCTOR PACKAGE

(71) Applicant: Samsung Electronics Co., Ltd., Suwon-si (KR)

(72) Inventors: Jin-Woo PARK, Suwon-si (KR); Un-Byoung KANG, Suwon-si (KR); Chung Sun LEE, Suwon-si (KR)

(21) Appl. No.: 18/455,922

(22) Filed: Aug. 25, 2023

(30) Foreign Application Priority Data
Aug. 26, 2022 (KR) 10-2022-0107744

(51) Int. Cl. H01L 25/065; H01L 23/00; H01L 23/498; H01L 25/10

(52) U.S. Cl. CPC H01L 25/0655; H01L 23/49822; H01L 23/49838; H01L 24/16; H01L 24/32; H01L 24/73; H01L 25/105; H01L 2224/16227; H01L 2224/16238; H01L 2224/32225; H01L 2224/73204; H01L 2225/1023; H01L 2225/1035; H01L 2225/1058; H01L 2924/182

(57) ABSTRACT

A semiconductor package includes a substrate; a substrate pad on the substrate; a first semiconductor chip and a second semiconductor chip on the substrate; a connective terminal between the substrate pad and the first semiconductor chip and between the substrate pad and the second semiconductor chip; a dummy pad on the substrate, and spaced apart from the substrate pad, wherein the dummy pad is between the first semiconductor chip and the second semiconductor chip; and an underfill material layer interposed between the substrate and the first semiconductor chip and between the substrate and the second semiconductor chip, wherein the dummy pad and the substrate pad include a same material.

### CROSS-REFERENCE TO RELATED APPLICATION

This application claims priority from Korean Patent Application No. 10-2022-0107744 filed on Aug. 26, 2022, in the Korean Intellectual Property Office, and all the benefits accruing therefrom under 35 U.S.C. 119, the contents of which in its entirety are herein incorporated by reference.

### BACKGROUND

### Field

The present disclosure relates to a semiconductor package.

### Description of Related Art

Recently, in the electronic products market, demand for portable devices is rapidly increasing. For this reason, miniaturization and weight reduction of electronic components mounted in electronic products are continuously required. For the miniaturization and weight reduction of an electronic component, a semiconductor package mounted thereon may be required to process large amounts of data while becoming smaller and smaller in volume. There is a demand for high integration and single packaging of semiconductor chips mounted on such a semiconductor package. Accordingly, to efficiently arrange the semiconductor chips within a limited semiconductor package structure, a system in package may be applied.

### SUMMARY

A technical purpose of the present disclosure is to provide a semiconductor package with improved product reliability.

Purposes according to the present disclosure are not limited to the above-mentioned purpose. Other purposes and advantages according to the present disclosure that are not mentioned may be understood based on following description, and may be more clearly understood based on embodiments according to the present disclosure. Further, it will be easily understood that the purposes and advantages according to the present disclosure may be realized using means shown in the claims and combinations thereof.

According to an aspect of the present disclosure, there is provided a semiconductor package comprising: a substrate; a substrate pad on the substrate; a first semiconductor chip and a second semiconductor chip on the substrate; a connective terminal between the substrate pad and the first semiconductor chip and between the substrate pad and the second semiconductor chip; a dummy pad on the substrate, and spaced apart from the substrate pad, wherein the dummy pad is between the first semiconductor chip and the second semiconductor chip; and an underfill material layer interposed between the substrate and the first semiconductor chip and between the substrate and the second semiconductor chip, wherein the dummy pad and the substrate pad comprise a same material.

According to another aspect of the present disclosure, there is provided a semiconductor package comprising: a substrate; a substrate pad on the substrate; a first semiconductor chip and a second semiconductor chip on the substrate and adjacent to each other; a connective terminal between the substrate pad and the first semiconductor chip and between the substrate pad and the second semiconductor chip; a dummy pad on the substrate, and spaced apart from the substrate pad, wherein the dummy pad is between the first semiconductor chip and the second semiconductor chip; and an underfill material layer interposed between the substrate and the first semiconductor chip and between the substate and the second semiconductor chip, wherein the underfill material layer extends along the dummy pad, wherein in a plan view of the semiconductor package, the dummy pad overlaps at least a portion of the first semiconductor chip and at least a portion of the second semiconductor chip.

According to another aspect of the present disclosure, there is provided a semiconductor package comprising: a substrate including a first face and a second face opposite to each other in a first direction; a substrate pad on the second face of the substrate; a first semiconductor chip and a second semiconductor chip on the second face of the substrate and adjacent to each other in the first direction; a third semiconductor chip on the second face of the substrate and adjacent to the first semiconductor chip in a second direction intersecting the first direction; a connective terminal configured to electrically connect a chip pad of each of the first to third semiconductor chip to the substrate pad; a dummy pad on the second face of the substrate, the dummy pad being between the first semiconductor chip and the second semiconductor chip and between the first semiconductor chip and the third semiconductor chip; and an underfill material layer in a space between the substrate and the first semiconductor chip, in a space between the substrate and the second semiconductor chip, and in a space between the substrate and the third semiconductor chip, wherein the underfill material layer is on the dummy pad, wherein the dummy pad and the substrate comprise a same material.

### BRIEF DESCRIPTION OF DRAWINGS

The above and other aspects and features of the present disclosure will become more apparent by describing in detail embodiments thereof with reference to the attached drawings, in which:

FIG. 1 is a diagram that illustrates a semiconductor package according to some embodiments;

FIG. 2 is an enlarged view of a R area of FIG. 1;

FIG. 3 is a cross-sectional view taken along I-I of FIG. 1;

FIGS. 4 to 12 are diagrams that illustrate a dummy pad of a semiconductor package according to some embodiments;

FIGS. 13 to 15 are diagrams that illustrate a semiconductor package according to some embodiments;

FIGS. 16 to 18 are diagrams that illustrate a semiconductor package according to some embodiments; and

FIG. 19 is a diagram that illustrate a semiconductor package according to some embodiments.

### DETAILED DESCRIPTION

Hereinafter, example embodiments will be described in detail with reference to the accompanying drawings. The present disclosure may, however, be embodied in many different forms and should not be construed as limited to the embodiments set forth herein. Like reference numerals refer to like elements throughout this application. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

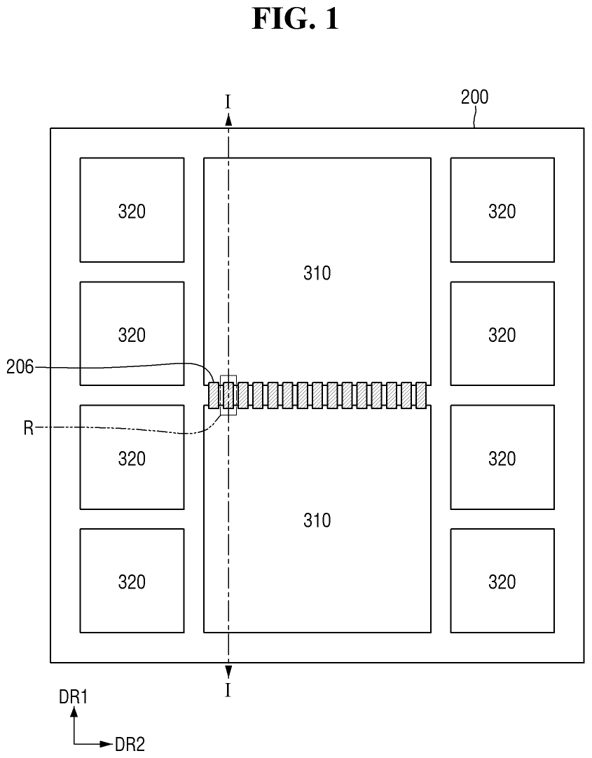

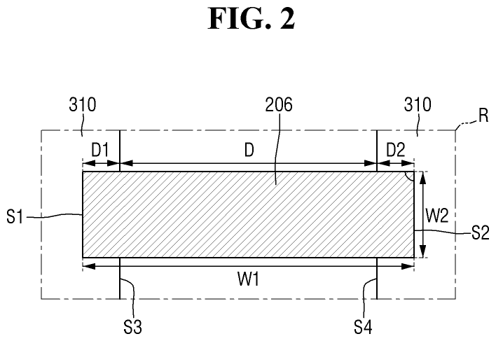

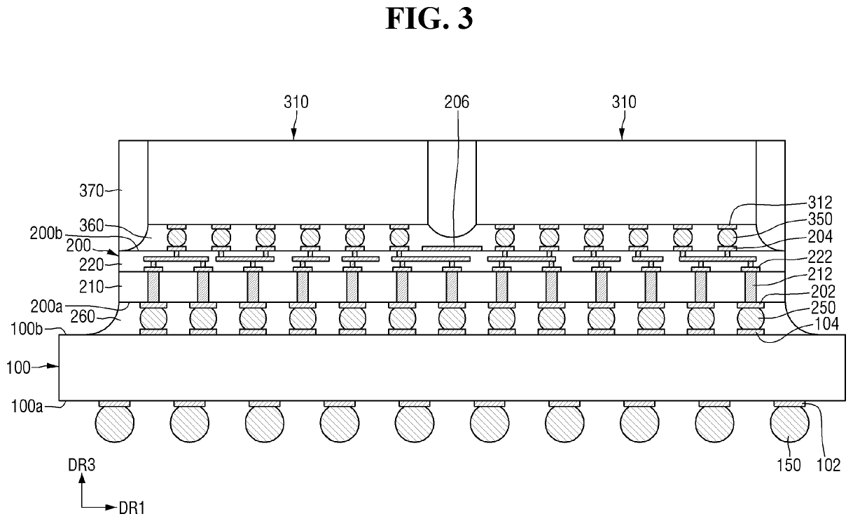

FIG. 1 is a diagram that illustrates a semiconductor package according to some embodiments. FIG. 2 is an enlarged view of a R area of FIG. 1. FIG. 3 is a cross-sectional view taken along I-I of FIG. 1.

Referring to FIGS. 1 to 3, the semiconductor package according to some embodiments may include a first substrate 100, an interposer 200, a plurality of first semiconductor chips 310 and a plurality of second semiconductor chips 320.

The first substrate 100 may include a bottom face 100a and a top face 100b opposite to each other. In the following description, the top face and the bottom face may be defined based on a third direction DR3. The third direction DR3 may be a direction perpendicular to the top face 100b of the first substrate 100. The first substrate 100 may include a first substrate pad 102 and a second substrate pad 104.

The first substrate pad 102 may be disposed on the bottom face 100a of the first substrate 100. The second substrate pad 104 may be disposed on the top face 100b of the first substrate 100. A solder resist layer exposing at least a portion of the first substrate pad 102 may be further disposed on the bottom face 100a of the first substrate 100, while a solder resist layer exposing at least a portion of the second substrate pad 104 may be further disposed on the top face 100b of the first substrate 100.

Each of the first substrate pad 102 and the second substrate pad 104 may include, for example, one or more metals, such as copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn) and carbon (C), or alloys including two or more metals thereof.

The first substrate 100 may include a base substrate and a multi-layer or single-layer based wiring pattern disposed in the base substrate. The wiring pattern may be electrically connected to the first substrate pad 102 and the second substrate pad 104. The base substrate may be made of one or more materials, such as phenol resin, epoxy resin, and/or polyimide. The first substrate 100 may act as a substrate for the package. The first substrate 100 may be embodied as, for example, a printed circuit board (PCB).

A first connective terminal 150 may be disposed on the first substrate pad 102 of the first substrate 100. The first connective terminal 150 may be electrically connected to the first substrate pad 102. The first substrate 100 may be mounted on a main board of an electronic device through the first connective terminal 150. The first connective terminal 150 may be embodied as, for example, a solder bump. However, embodiments of the present disclosure are not limited thereto. The first connective terminal 150 may have various shapes, such as a land, a ball, a pin, and a pillar.

The interposer 200 may be disposed on the top face 100b of the first substrate 100. The top face 100b of the first substrate 100 may face a bottom face 200a of the interposer 200.

The interposer 200 may include a first interposer pad 202, a second interposer pad 204, a dummy pad 206, a base layer 210, a through electrode 212, a wiring insulating layer 220 and a wiring pattern 222.

The first interposer pad 202 may be disposed on the bottom face 200a of the interposer 200. The second interposer pad 204 may be disposed on the top face 200b of the interposer 200. The interposer 200 may be referred to as a substrate, and each of the first interposer pad 202 and the second interposer pad 204 may be referred to as a substrate pad.

The dummy pad 206 may be disposed on the top face 200b of the interposer 200. The dummy pad 206 may be spaced apart from the second interposer pad 204. The dummy pad 206 may be formed in the same process as a process in which the second interposer pad 204 is formed. The dummy pad 206 may include the same material as that of the second interposer pad 204. On the top face 200b of the interposer 200, a thickness of the dummy pad 206 may be substantially equal to a thickness of the second interposer pad 204. A top face of the dummy pad 206 may be substantially coplanar with a top face of the second interposer pad 204.

The dummy pad 206 may not be electrically connected to the wiring pattern 222 and semiconductor chips 310 and 320.

A bottom face of the base layer 210 may act as a bottom face 200a of the interposer 200. The base layer 210 may include a semiconductor material, glass, ceramic, and/or plastic. The base layer 210 may include, for example, silicon.

The through electrode 212 may be electrically connected to the first interposer pad 202 and the wiring pattern 222. For example, the through electrode 212 may extend through the base layer 210.

The wiring insulating layer 220 may be disposed on the base layer 210. A top face of the wiring insulating layer 220 may act as a top face of the interposer 200. The wiring insulating layer 220 may include, for example, one or more materials, such as silicon oxide, silicon nitride, silicon oxynitride, a low-k material having a dielectric constant lower than that of silicon oxide, and/or PID (Photo Imageable dielectric), such as polyimide.

The wiring pattern 222 may include a plurality of wiring layers positioned at different levels in the wiring insulating layer 220 to form a multi-layered structure, and a conductive via disposed in the wiring insulating layer 220 and extending in the third direction DR3 to connect the plurality of wiring layers to each other. Each of the through electrode 212 and the wiring pattern 222 may include, for example, a metal material, such as tungsten (W), aluminum (Al), nickel (Ni), and/or copper (Cu). However, embodiments of the present disclosure are not limited thereto.

A second connective terminal 250 may be disposed between the first substrate 100 and the interposer 200. The second connective terminal 250 may be electrically connected to the second substrate pad 104 of the first substrate 100 and the first interposer pad 202 of the interposer 200. Accordingly, the first substrate 100 may be electrically connected to the interposer 200.

The second connective terminal 250 may be embodied, for example, as a solder bump including a low melting point metal, for example, tin (Sn), or a tin (Sn) alloy, etc. However, embodiments of the present disclosure are not limited thereto. The second connective terminal 250 may have various shapes, such as a land, a ball, a pin, and a pillar. The second connective terminal 250 may be composed of a single layer or multiple layers. When the second connective terminal 250 is compose of a single layer, the second connective terminal 250 may include, for example, tin-silver (Sn—Ag) solder and/or copper (Cu). When the second connective terminal 250 is composed of multiple layers, the second connective terminal 250 may include, for example, copper (Cu) pillar and solder.

A first underfill material layer 260 may be disposed between the first substrate 100 and the interposer 200. The first underfill material layer 260 may be in and at least partially fill a space between the first substrate 100 and the interposer 200. The first underfill material layer 260 may border or at least partially surround the second connective terminal 250. The first underfill material layer 260 may include, but is not limited to, an insulating polymer material, such as an EMC (epoxy molding compound).

In the semiconductor package according to some embodiments, the semiconductor chips 310 and 320 may be mounted on the interposer 200. A first semiconductor chip 310 and a second semiconductor chip 320 may be spaced apart from each other and disposed on the top face 200b of the interposer 200. For example, the second semiconductor chip 320 may be disposed around the first semiconductor chip 310. In an example, two second semiconductor chips 320 may be respectively disposed on both opposing sides in the first direction DR1 of the first semiconductor chip 310. The second semiconductor chips 320 may be spaced apart from each other in the second direction DR2. Each of the number of the first semiconductor chips 310 and the number of the second semiconductor chips 320 is not limited to the number as shown in the drawing. In addition, the semiconductor package according to some embodiments may further include a dummy chip.

In some embodiments, the first semiconductor chip 310 may be embodied as a logic semiconductor chip. For example, the first semiconductor chip 310 may be embodied as an application processor (AP) such as CPU (Central Processing Unit), GPU (Graphic Processing Unit), FPGA (Field-Programmable Gate Array), DSP (Digital Signal Processor), CP (Cryptographic Processor), a microprocessor, a microcontroller, or ASIC (Application-Specific IC), etc. However, embodiments of the present disclosure are not limited thereto.

In some embodiments, the second semiconductor chip 320 may be embodied as a memory semiconductor chip. For example, the second semiconductor chip 320 may be embodied as a volatile memory, such as DRAM (dynamic random access memory) or SRAM (static random access memory), or as a non-volatile memory, such as a flash memory, PRAM (Phase-change Random Access Memory), MRAM (Magnetoresistive Random Access Memory), FeRAM (Ferroelectric Random Access Memory) or RRAM (Resistive Random Access Memory).

For example, the first semiconductor chip 310 may be embodied as an ASIC, such as a GPU, while the second semiconductor chip 320 may be embodied as a stack memory, such as a high-bandwidth memory (HBM). The stack memory may be in a form in which a plurality of integrated circuits are stacked. The stacked integrated circuits may be electrically connected to each other via a TSV (Through Silicon Via) or the like.

The first semiconductor chip 310 may include a first chip pad 312. The first chip pad 312 may be disposed on a bottom face of the first semiconductor chip 310. The first chip pad 312 may include, for example, a metal material, such as copper (Cu) or aluminum (Al). However, embodiments of the present disclosure are not limited thereto.

A third connective terminal 350 may be disposed between the interposer 200 and the first semiconductor chip 310. The third connective terminal 350 may contact the second interposer pad 204 of the interposer 200 and the first chip pad 312 of the first semiconductor chip 310. The third connective terminal 350 may be electrically connected to the second interposer pad 204 of the interposer 200 and the first chip pad 312 of the first semiconductor chip 310. Accordingly, the first semiconductor chip 310 may be electrically connected to the interposer 200.

The third connective terminal 350 may be embodied as a solder bump including a low melting point metal, for example, tin (Sn) or a tin (Sn) alloy. However, embodiments of the present disclosure are not limited thereto. The third connective terminal 350 may have various shapes, such as a land, a ball, a pin, and a pillar. The third connective terminal 350 may include, but is not limited to, UBM (Under Bump Metallurgy). The number, spacing, arrangement, etc. of the first connective terminals 150 are not limited to those shown, and may vary depending on a design. The number, spacing, arrangement, etc. of the second connective terminals 250 are not limited to those shown, and may vary depending on a design. The number, spacing, arrangement, etc. of the third connective terminals 350 are not limited to those shown, and may vary depending on a design.

The second semiconductor chip 320 may also include a second chip pad. The third connective terminal 350 may contact and may be electrically connected to the second chip pad and the second interposer pad 204 of the interposer 200. Accordingly, the second semiconductor chip 320 may be electrically connected to the interposer 200.

The dummy pad 206 may be disposed between the semiconductor chips 310 and 320 adjacent to each other. The dummy pad 206 may be disposed between the semiconductor chips 310 and 320 adjacent to each other and may extend along the semiconductor chips 310 and 320. The dummy pads 206 may be arranged to be spaced from each other, for example, by a constant spacing. In another example, the dummy pads 206 may be arranged to be spaced from each other by various spacings.

In the semiconductor package according to some embodiments, the dummy pad 206 may be disposed in an area adjacent to a center point of the interposer 200. The dummy pad 206 may be disposed between the first semiconductor chips 310. The dummy pad 206 may be disposed between the first semiconductor chips 310 adjacent to each other in the first direction DR1. The dummy pads 206 may be arranged in the second direction DR2 while being disposed between the first semiconductor chips 310 adjacent to each other in the first direction DR1. One first semiconductor chip 310 including a third sidewall S3 and another first semiconductor chip 310 including a fourth sidewall S4 may be adjacent to each other in the first direction DR1. The sidewall S3 of the first semiconductor chip 310 may face the sidewall S4 of the first semiconductor chip 310. The dummy pads 206 may be arranged along the third sidewall S3 and/or the fourth sidewall S4.

In a plan view of the semiconductor package according to some embodiments, the dummy pad 206 may overlap at least a portion of each of the semiconductor chips 310 and 320 adjacent to each other. The dummy pad 206 may overlap with at least a portion of the first semiconductor chip 310 including the third sidewall S3 and at least a portion of the first semiconductor chip 310 including the fourth sidewall S4 in the third direction DR3. A width W1 in the first direction DR1 of the dummy pad 206 may be greater than a spacing D between the first semiconductor chips 310 adjacent to each other in the first direction DR1.

In other words, the dummy pad 206 may include a first sidewall S1 and a second sidewall S2 opposite to each other in the first direction DR1. The first sidewall S1 of the dummy pad 206 may be adjacent to the first semiconductor chip 310 including the third sidewall S3, while the second sidewall S2 of the dummy pad 206 may be adjacent to the first semiconductor chip 310 including the fourth sidewall S4. The first sidewall S1 of the dummy pad 206 may be disposed under the first semiconductor chip 310 including the third sidewall S3, while the second sidewall S2 of the dummy pad 206 may be disposed under the first semiconductor chip 310 including the fourth sidewall S4. In this regard, “being disposed below” may be based on the third direction DR3. The first sidewall S1 may be close to the third sidewall S3, and the second sidewall S2 may be close to the fourth sidewall S4. The first sidewall S1 may be closer to the third sidewall S3 than to the fourth sidewall S4. The second sidewall S2 may be closer to the fourth sidewall S4 than to the second sidewall S3.

In the semiconductor package according to some embodiments, an area by which the dummy pad 206 overlaps with the first semiconductor chip 310 including the third sidewall S3 in the third direction DR3 may be substantially equal to an area by which the dummy pad 206 overlaps with the first semiconductor chip 310 including the fourth sidewall S4 in the third direction DR3. A spacing D1 between the first sidewall S1 and the third sidewall S3 may be substantially equal to a spacing D2 between the second sidewall S2 and the fourth sidewall S4.

In the semiconductor package according to some embodiments, the dummy pad 206 may have a polygonal shape in a plan view. The dummy pad 206 may have, for example, a rectangular shape or a bar shape in a plan view. In other embodiments, the dummy pad 206 may have a shape of, for example, a triangle, a rhombus, a hexagon, an octagon, etc. in a plan view.

In the semiconductor package according to some embodiments, a width W1 in the first direction DR1 of the dummy pad 206 may be different from a width W2 in the second direction DR2 of the dummy pad 206. For example, the width W1 in the first direction DR1 of the dummy pad 206 may be greater than the width W2 in the second direction DR2 of the dummy pad 206.

In the semiconductor package according to some embodiments, the width W1 in the first direction DR1 of the dummy pad 206 may be substantially equal to the width W2 in the second direction DR2 of the dummy pad 206. The dummy pad 206 may have a square shape in a plan view.

A second underfill material layer 360 may be disposed between each of the first and second semiconductor chips 310 and 320 and the interposer 200. The second underfill material layer 360 may be in and at least partially fill a space between each of the first and second semiconductor chips 310 and 320 and the interposer 200. The second underfill material layer 360 may border and at least partially surround the third connective terminal 350. The second underfill material layer 360 may include, for example, an insulating polymer material, such as an EMC (epoxy molding compound). However, embodiments of the present disclosure are not limited thereto.

The second underfill material layer 360 may be disposed on the dummy pad 206. The second underfill material layer 360 may be on and at least partially cover the dummy pad 206. The second underfill material layer 360 may extend along the dummy pad 206 and may be disposed between each of the semiconductor chips 310 and 320 respectively disposed on both opposing sides of the dummy pad 206 and the interposer 200. For example, the second underfill material layer 360 may be in and at least partially fill a space between the first semiconductor chip 310 including the third sidewall S3 and the interposer 200 and may extend along dummy pad 206 and may be in and at least partially fill a space between the first semiconductor chip 310 including the fourth sidewall S4 and the interposer 200.

The second underfill material layer 360 may be formed by curing an underfill solution injected from a dispenser nozzle onto one side of each of the semiconductor chips 310 and 320. At this time, the underfill solution injected on one side of each of the semiconductor chips 310 and 320 may flow along the dummy pad 206 and thus may flow into a space between each of the neighboring semiconductor chips 310 and 320 and the interposer 200. Therefore, a formation time of the second underfill material layer 360 may be shortened.

Further, when the spacing between the semiconductor chips 310 and 320 adjacent to each other is smaller, it may be difficult to inject the underfill solution into a space between the semiconductor chips 310 and 320 adjacent to each other. However, in the semiconductor package according to some embodiments, there is no need to inject the underfill solution into the space between the neighboring semiconductor chips 310 and 320 using the dummy pad 206. Rather, in accordance with embodiments of the present disclosure, the underfill solution may be injected onto one side of each of the semiconductor chips 310 and 320 close to a sidewall of the interposer 200. Then, the underfill solution may be cured to form the second underfill material layer 360.

A molding member 370 may be disposed on the top face 200b of the interposer 200. The molding member 370 may be on and cover at least a portion of each of the semiconductor chips 310 and 320. For example, the molding member 370 may at least partially cover a side face of the first semiconductor chip 310, a side face of the second semiconductor chip 320, and the second underfill material layer 360. For example, the molding member 370 may expose a top face of the first semiconductor chip 310 and a top face of the second semiconductor chip 320. In other embodiments, the molding member 370 may at least partially cover a top face of the first semiconductor chip 310 and a top face of the second semiconductor chip 320. The molding member 370 may include, for example, an insulating polymer material such as EMC. However, the embodiments of present disclosure are not limited thereto.

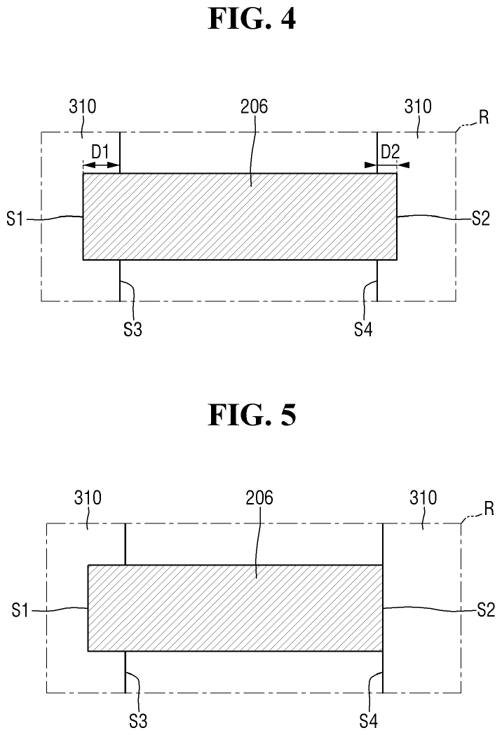

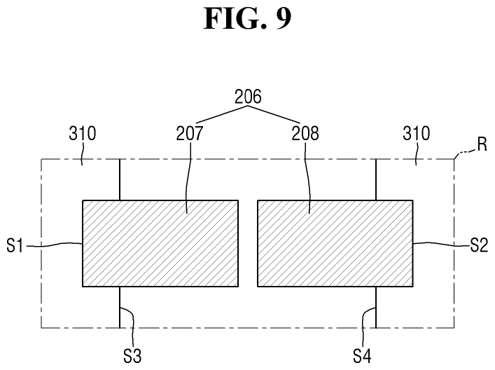

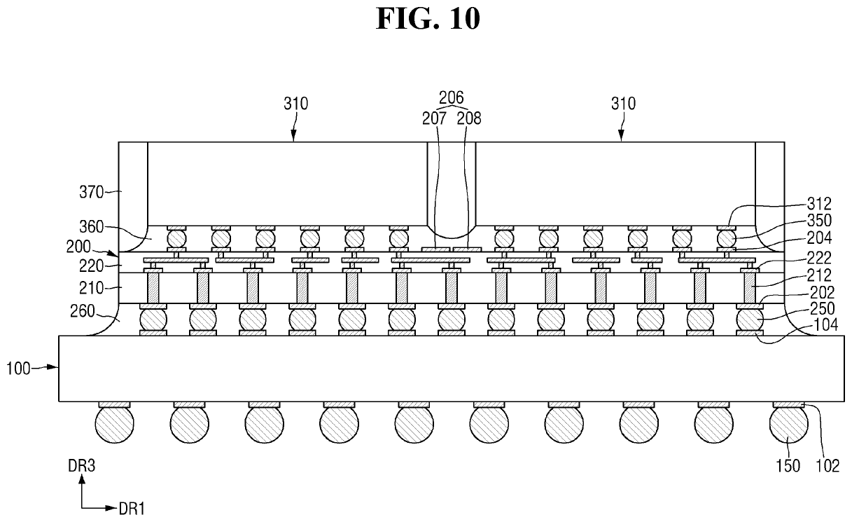

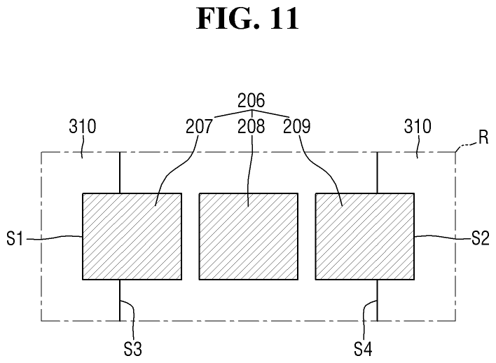

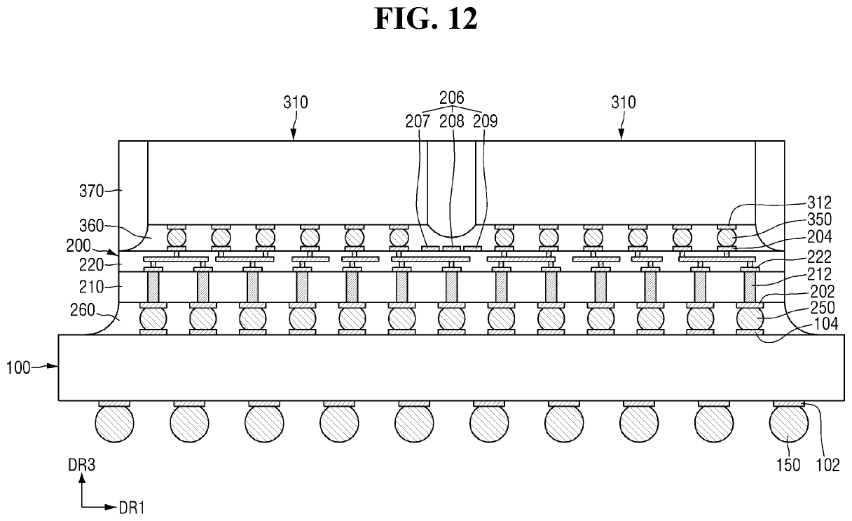

FIGS. 4 to 12 are diagrams that illustrate a dummy pad of a semiconductor package according to some embodiments. FIGS. 4 to 11 are enlarged views of a R area of FIG. 1. FIG. 10 is a cross-sectional view taken along I-I of FIG. 1 when the enlarged view of the R area of FIG. 1 is FIG. 9. FIG. 12 is a cross-sectional view taken along I-I of FIG. 1 when the enlarged view of the R area of FIG. 1 is FIG. 11. For convenience of description, the following description is based on differences from those set forth above with reference to FIGS. 1 to 3.

Referring to FIG. 4, in the semiconductor package according to some embodiments, an area by which the dummy pad 206 overlaps with the first semiconductor chip 310 including the third sidewall S3 in the third direction DR3 may be different from an area by which the dummy pad 206 overlaps with the first semiconductor chip 310 including the fourth sidewall S4 in the third direction DR3. The spacing D1 between the first sidewall S1 and the third sidewall S3 may be different from the spacing D2 between the second sidewall S2 and the fourth sidewall S4. For example, the area by which the dummy pad 206 overlaps with the first semiconductor chip 310 including the third sidewall S3 in the third direction DR3 may be larger than the area by which the dummy pad 206 overlaps with the first semiconductor chip 310 including the fourth sidewall S4 in the third direction DR3, while the spacing D1 between the first sidewall S1 and the third sidewall S3 may be greater than the spacing D2 between the second sidewall S2 and the fourth sidewall S4. In other embodiments, the area by which the dummy pad 206 overlaps with the first semiconductor chip 310 including the third sidewall S3 in the third direction DR3 may be smaller than the area by which the dummy pad 206 overlaps with the first semiconductor chip 310 including the fourth sidewall S4 in the third direction DR3, while the spacing D1 between the first sidewall S1 and the third sidewall S3 may be smaller than the spacing D2 between the second sidewall S2 and the fourth sidewall S4.

Referring to FIG. 5, in the semiconductor package according to some embodiments, one sidewall of the dummy pad 206, and one sidewall of the semiconductor chip 310 may constitute the same plane extending in the third direction DR3. For example, the second sidewall S2 of the dummy pad 206, and the fourth sidewall S4 of the first semiconductor chip 310 may constitute the same plane extending in the third direction DR3, while the first sidewall S1 of the dummy pad 206 may be disposed under the first semiconductor chip 310 including the third sidewall S3. In other embodiments, the first sidewall S1 of the dummy pad 206 and the third sidewall S3 of the first semiconductor chip 310 may constitute the same plane extending in the third direction DR3, while the second sidewall S2 of the dummy pad 206 may be disposed under the first semiconductor chip 310 including the fourth sidewall S4.

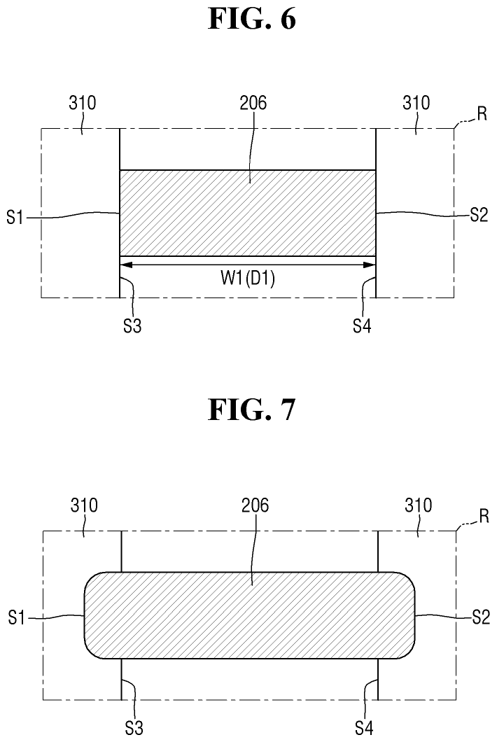

Referring to FIG. 6, in the semiconductor package according to some embodiments, the first sidewall S1 of the dummy pad 206 and the third sidewall S3 of the first semiconductor chip 310 may constitute the same plane extending in the third direction DR3, while the second sidewall S2 of the dummy pad 206 and the fourth sidewall S4 of the first semiconductor chip 310 may constitute the same plane extending in the third direction DR3.

A width W1 in the first direction DR1 of the dummy pad 206 may be substantially equal to a spacing D between the first semiconductor chips 310 adjacent to each other in the first direction DR1.

Referring to FIG. 7, in the semiconductor package according to some embodiments, the dummy pad 206 may have a rectangular shape with rounded corners in a plan view.

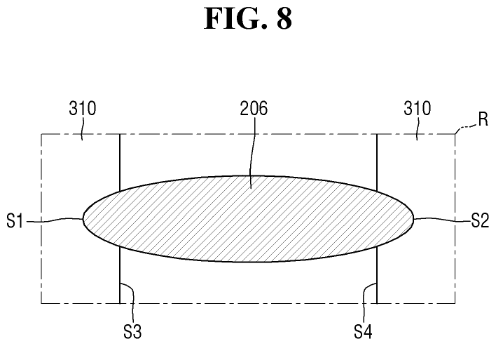

Referring to FIG. 8, in the semiconductor package according to some embodiments, the dummy pad 206 may have a circular shape in a plan view. The dummy pad 206 may have, for example, an elliptical shape in a plan view.

Referring to FIGS. 9 and 10, in the semiconductor package according to some embodiments, the dummy pad 206 may include first and second dummy pads 207 and 208 spaced apart from each other.

Each of the first dummy pad 207 and the second dummy pad 208 may overlap with the first semiconductor chip 310 in the third direction DR3. For example, the first dummy pad 207 may be adjacent to the second dummy pad 208 in the first direction DR1, and the first dummy pad 207 may overlap the first semiconductor chip 310 including the third sidewall S3 in the third direction DR3, and the second dummy pad 208 may overlap the first semiconductor chip 310 including the fourth sidewall S4 in the third direction DR3. That is, the first sidewall S1 of the first dummy pad 207 may be disposed under the first semiconductor chip 310 including the third sidewall S3, while the second sidewall S2 of the second dummy pad 208 may be disposed under the first semiconductor chip 310 including the fourth sidewall S4.

In other embodiments, a sidewall in the opposite direction to the first direction DR1 of the first dummy pad 207 may be aligned with the third sidewall S3 of the first semiconductor chip 310 in the third direction DR3; or a sidewall in the first direction DR1 of the second dummy pad 208 may be aligned with the fourth sidewall S4 of the first semiconductor chip 310 in the third direction DR3.

Referring to FIG. 11 and FIG. 12, in the semiconductor package according to some embodiments, the dummy pad 206 may include a plurality of dummy pads 207, 208, and 209 spaced apart from each other. Each of the dummy pads 206 may have a dotted line shape in a plan view. For example, the first to third dummy pads 207, 208, and 209 may be sequentially arranged along the first direction DR1. The first dummy pad 207 may overlap with the first semiconductor chip 310 including the third sidewall S3 in the third direction DR3, while the third dummy pad 209 may overlap the first semiconductor chip 310 including the fourth sidewall S4 in the third direction DR3.

In other embodiments, the sidewall in the opposite direction to the first direction DR1 of the first dummy pad 207 may be aligned with the third sidewall S3 of the first semiconductor chip 310 in the third direction DR3; or the sidewall in the first direction DR1 of the third dummy pad 209 may be aligned with the fourth sidewall S4 of the first semiconductor chip 310 in the third direction DR3.

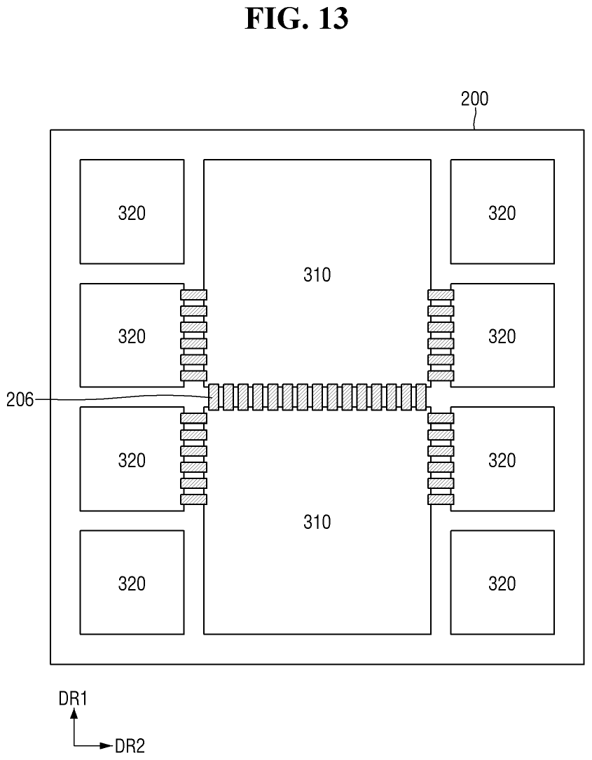

FIGS. 13 to 15 are diagrams for illustrating a semiconductor package according to some embodiments. For convenience of description, the following description is based on differences from those set forth above with reference to FIGS. 1 to 12.

Referring to FIG. 13, in the semiconductor package according to some embodiments, the dummy pad 206 may be disposed in an area adjacent to the center point of the interposer 200 and/or an area positioned between the first semiconductor chip 310 and the second semiconductor chip 320 adjacent to each other. For example, the dummy pad 206 may be further disposed between the first semiconductor chip 310 and the second semiconductor chip 302 neighboring to each other in the second direction DR2.

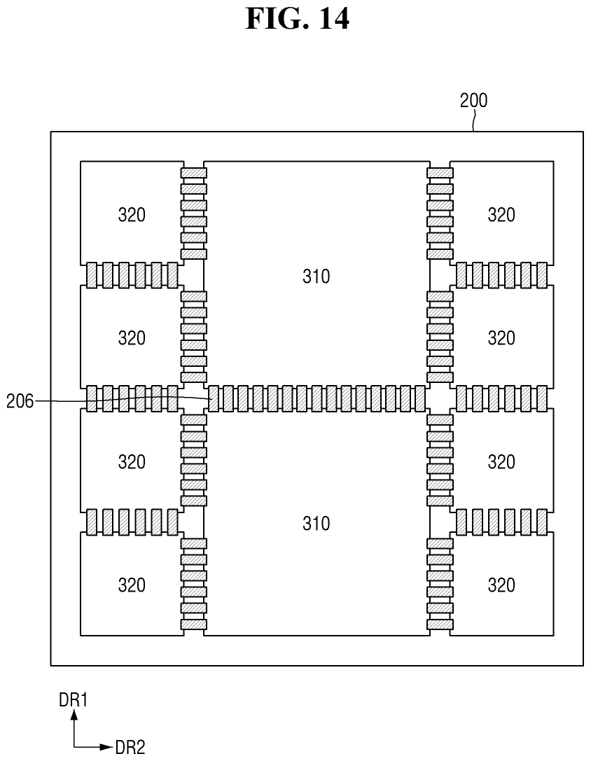

Referring to FIG. 14, in the semiconductor package according to some embodiments, the dummy pads 206 may be disposed in all of the areas positioned between the semiconductor chips 310 and 320 adjacent to each other. The dummy pad 206 may be disposed between the first semiconductor chip 310 and the second semiconductor chip 320 adjacent to each other, between the first semiconductor chips 310 adjacent to each other, and between the second semiconductor chips 320 adjacent to each other.

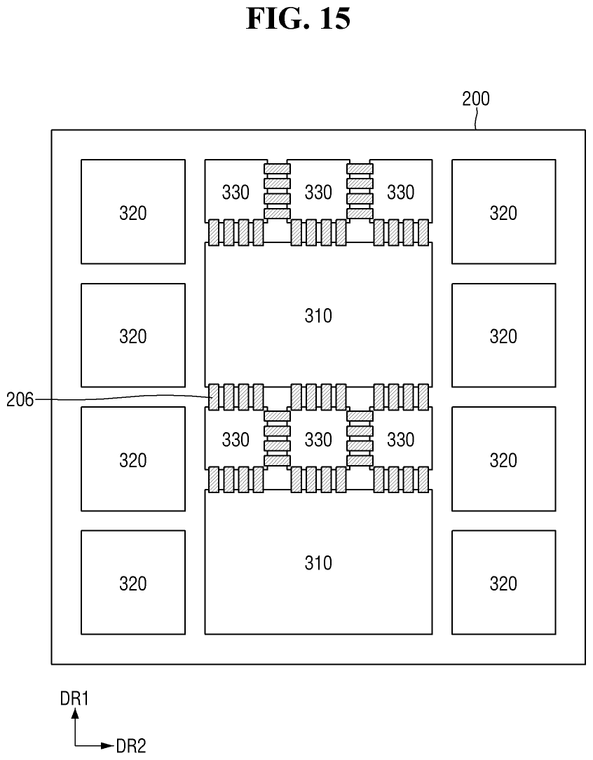

Referring to FIG. 15, the semiconductor package according to some embodiments may further include a plurality of chiplets 330. For example, the chiplets 330 may be adjacent to the first semiconductor chip 310 in the first direction DR1 and may be arranged in the second direction DR2. The chiplets 330 may be disposed between the first semiconductor chips 310 adjacent to each other.

The chiplet 330 may include one or more of a process chip, a logic chip, a memory chip, and the like.

The dummy pad 206 may be disposed between each of the semiconductor chips 310 and 320 and the chiplet 330 adjacent to each other or between adjacent ones of the chiplets 330. For example, the dummy pad 206 may be disposed between adjacent ones of the chiplets 330 and between the chiplet 330 and the first semiconductor chip 310 adjacent to each other.

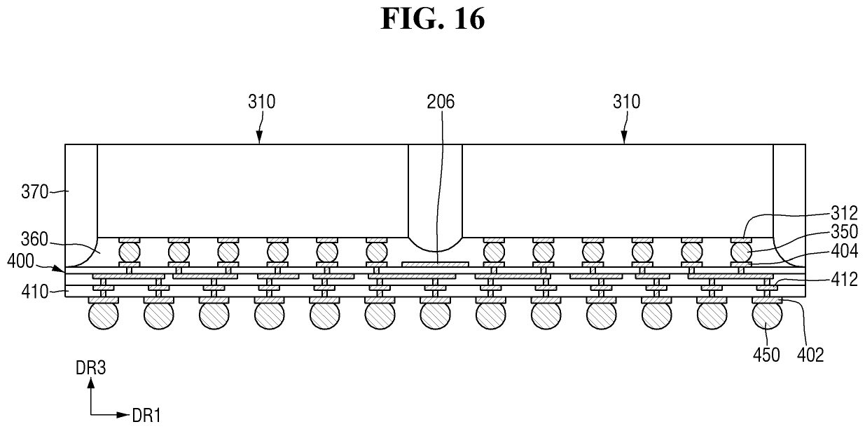

FIGS. 16 to 19 are diagrams that illustrate a semiconductor package according to some embodiments. For convenience of description, the following description is based on differences from those set forth above with reference to FIGS. 1 to 15.

Referring to FIG. 16, in the semiconductor package according to some embodiments, the semiconductor chip 310 may be mounted on a redistribution substrate 400. The redistribution substrate 400 may include a bottom face 400a and a top face 400b opposite to each other. The semiconductor chip 310 may be disposed on the top face 400b of the redistribution substrate 400. The following description is based on an example in which the first semiconductor chip 310 is mounted on the redistribution substrate 400. However, embodiments of the present disclosure are not limited thereto. The first semiconductor chip 310, the second semiconductor chip (320 in FIG. 1), or the chiplet (330 in FIG. 16) may be mounted on the redistribution substrate 400.

The redistribution substrate 400 may include a first redistribution pad 402, a second redistribution pad 404, the dummy pad 206, a redistribution insulating layer 410, and a redistribution pattern 412.

The first redistribution pad 402 may be disposed on the bottom face 400a of the redistribution substrate 400. The second redistribution pad 404 may be disposed on the top face 400b of the redistribution substrate 400. The redistribution substrate 400 may be referred to as a substrate, and each of the first redistribution pad 402 and the second redistribution pad 404 may be referred to as a substrate pad.

The third connective terminal 350 may be disposed between the first chip pad 312 of the first semiconductor chip 310 and the second redistribution pad 404 of the redistribution substrate 400. The third connective terminal 350 may contact the first chip pad 312 of the first semiconductor chip 310 and the second redistribution pad 404 of the redistribution substrate 400. A fourth connective terminal 450 may be disposed on the first redistribution pad 402 of the redistribution substrate 400. The fourth connective terminal 450 may be embodied as, for example, a solder bump. However, embodiments of the present disclosure are not limited thereto. The fourth connective terminal 450 may have various shapes, such as a land, a ball, a pin, and a pillar. The number, spacing, arrangement, etc. of the fourth connective terminals 450 are not limited to those as shown, and may vary depending on the design.

The dummy pad 206 may be disposed on the top face 400b of the redistribution substrate 400. The dummy pad 206 may be spaced apart from the second redistribution pad 404. The dummy pad 206 may be formed in the same process as a process in which the second redistribution pad 404 is formed. The dummy pad 206 may include the same material as that of the second redistribution pad 404. On the top face 400b of the redistribution substrate 400, a thickness of the second redistribution pad 404 may be substantially equal to a thickness of the dummy pad 206. The dummy pad 206 may not be electrically connected to the redistribution substrate 400 and the first semiconductor chip 310.

The redistribution insulating layer 410 may have a structure of layers stacked in the third direction DR3. The redistribution insulating layer 410 may include, for example, one or more materials, such as silicon oxide, silicon nitride, silicon oxynitride, a low-k material having a dielectric constant lower than that of silicon oxide, and/or PID (Photo Imageable Dielectric) such as polyimide. Boundaries between the redistribution insulating layers 410 may not be clearly defined.

The redistribution pattern 412 may include a stack of a plurality of wiring layers disposed in the redistribution insulating layer 410 and positioned at different levels, and conductive vias disposed in the redistribution insulating layer 410 and extending in the third direction DR3 to connect the plurality of wiring layers to each other. The redistribution pattern 412 may include, but is not limited to, a metal material including, for example, copper (Cu), aluminum (Al), silver (Ag), tin (Sn), gold (Au), nickel (Ni), lead (Pb), titanium (Ti), or alloys thereof.

The second underfill material layer 360 may be disposed between the first semiconductor chip 310 and the redistribution substrate 400. The second underfill material layer 360 may be disposed on the dummy pad 206. The second underfill material layer 360 may be on and at least partially cover the dummy pad 206. The second underfill material layer 360 may extend along the dummy pad 206 and be in and at least partially fill an space between the first semiconductor chip 310 and the redistribution substrate 400 respectively disposed on both opposing sides of the dummy pad 206.

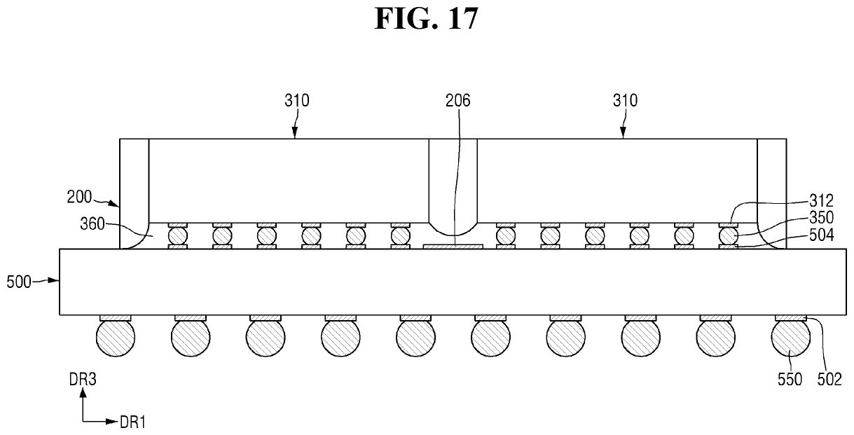

Referring to FIG. 17, in the semiconductor package according to some embodiments, the semiconductor chip 310 may be mounted on a second substrate 500. The second substrate 500 may include a bottom face 500a and a top face 500b opposite to each other. The semiconductor chip 310 may be disposed on the top face 500b of the second substrate 500. The following description is based on an example in which the first semiconductor chip 310 is mounted on the second substrate 500. However, embodiments of the present disclosure are not limited thereto. The first semiconductor chip 310, the second semiconductor chip (320 in FIG. 1) or the chiplet (330 in FIG. 16) may be mounted on the second substrate 500.

The second substrate 500 may include a third substrate pad 502, a fourth substrate pad 504 and the dummy pad 206. The second substrate 500 may be embodied as a substrate for a package.

The third substrate pad 502 may be disposed on the bottom face 500a of the second substrate 500. The fourth substrate pad 504 may be disposed on the top face 500b of the second substrate 500. A solder resist layer exposing at least a portion of the third substrate pad 502 may be further disposed on the bottom face 500a of the second substrate 500, while a solder resist layer exposing at least a portion of the fourth substrate pad 504 may be further disposed on the top face 500b of the second substrate 500. The third connective terminal 350 may contact the first chip pad 312 of the first semiconductor chip 310 and the fourth substrate pad 504 of the second substrate 500.

The second substrate 500 may include a base substrate and a multi-layer or single-layer-based wiring pattern disposed in the base substrate, wherein the wiring pattern may be electrically connected to the third substrate pad 502 and the fourth substrate pad 504.

A fifth connective terminal 550 may be disposed on the third substrate pad 502 of the second substrate 500. The fifth connective terminal 550 may have various shapes, such as a land, a ball, a pin, a pillar, and the like. The number, spacing, arrangement, etc. of the fifth connective terminal 550 are not limited to those as shown, and may vary depending on the design.

The dummy pad 206 may be disposed on the top face 500b of the second substrate 500. The dummy pad 206 may be spaced apart from the fourth substrate pad 504. The dummy pad 206 may be formed in the same process as a process in which the fourth substrate pad 504 is formed. The dummy pad 206 may include the same material as that of the fourth substrate pad 504. On the top face 500b of the second substrate 500, a thickness of the dummy pad 206 may be substantially equal to a thickness of the fourth substrate pad 504. The dummy pad 206 may not be electrically connected to the second substrate 500 and the first semiconductor chip 310.

The second underfill material layer 360 may be disposed between the first semiconductor chip 310 and the second substrate 500. The second underfill material layer 360 may be disposed on the dummy pad 206. The second underfill material layer 360 may be on and at least partially cover the dummy pad 206. The second underfill material layer 360 may extend along the dummy pad 206 and be in and at least partially fill a space between the first semiconductor chip 310 and the second substrate 500 respectively disposed on both opposing sides of the dummy pad 206.

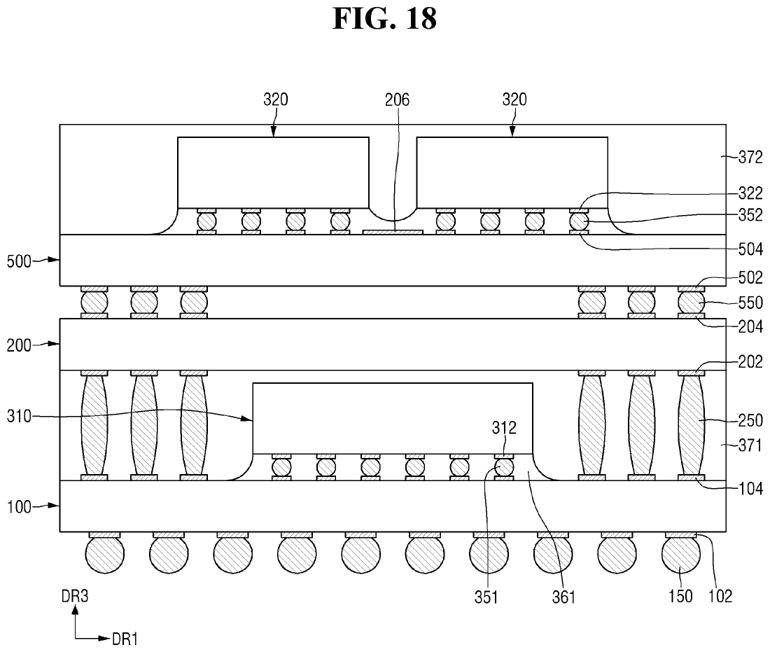

Referring to FIG. 18, the semiconductor package according to some embodiments may include the first substrate 100, the first and second semiconductor chips 310 and 320, the interposer 200, and the second substrate 500.

The first semiconductor chip 310 may be mounted on the first substrate 100. A third-first connective terminal 351 may be disposed between the first chip pad 312 of the first semiconductor chip 310 and the second substrate pad 104 of the first substrate 100. The third-first connective terminal 351 may be electrically connected to the first chip pad 312 of the first semiconductor chip 310 and the second substrate pad 104 of the first substrate 100. A second-first underfill material layer 361 may be in and at least partially fill a space between the first semiconductor chip 310 and the first substrate 100. The second-first underfill material layer 361 may border and at least partially surround the third-first connective terminal 351.

A first molding member 371 may be disposed on the first substrate 100. The first molding member 371 may be on and cover at least a portion of the first semiconductor chip 310. For example, the first molding member 371 may at least partially cover the first semiconductor chip 310 and the second-first underfill material layer 361. The first molding member 371 may include, for example, an insulating polymer material such as EMC. However, embodiments of the present disclosure is not limited thereto.

The interposer 200 may be mounted on the first substrate 100 and the first semiconductor chip 310. The second connective terminal 250 may be disposed in the first molding member 371. The first molding member 371 may be in and at least partially fill a space between the first substrate 100 and the interposer 200. The second connective terminal 650 may extend through the first molding member 371.

The second substrate 500 may be disposed on the interposer 200. A fifth connective terminal 550 may be disposed between the second interposer pad 204 of the interposer 200 and the third substrate pad 502 of the second substrate 500. The fifth connective terminal 550 may be electrically connected to the second interposer pad 204 of the interposer 200 and the third substrate pad 502 of the second substrate 500.

The second semiconductor chip 320 may be mounted on the second substrate 500. A third-second connective terminal 352 may be disposed between the second chip pad 322 of the second semiconductor chip 320 and the fourth substrate pad 504 of the second substrate 500. The third-second connective terminal 352 may be electrically connected to the second chip pad 322 of the second semiconductor chip 320 and the fourth substrate pad 504 of the second substrate 500.

The dummy pad 206 may be disposed between the second semiconductor chips 320 adjacent to each other. A second-second underfill material layer 362 may be disposed between the second semiconductor chip 310 and the second substrate 500. The second-second underfill material layer 362 may be disposed on the dummy pad 206. The second-second underfill material layer 362 may be on and at least partially cover the dummy pad 206. The second-second underfill material layer 362 may extend along the dummy pad 206 and be in and at least partially fill a space between the second semiconductor chip 320 and the second substrate 500 respectively disposed on both opposing sides of the dummy pad 206. The second-second underfill material layer 362 may border and at least partially surround the third-second connective terminal 352.

A second molding member 372 may be disposed on the second substrate 500. The second molding member 372 may be on and cover at least a portion of the second semiconductor chip 320. For example, the second molding member 372 may at least partially cover the second semiconductor chip 320 and the second-second underfill material layer 362. The second molding member 372 may include, for example, an insulating polymer material such as EMC. However, embodiments of the present disclosure are not limited thereto.

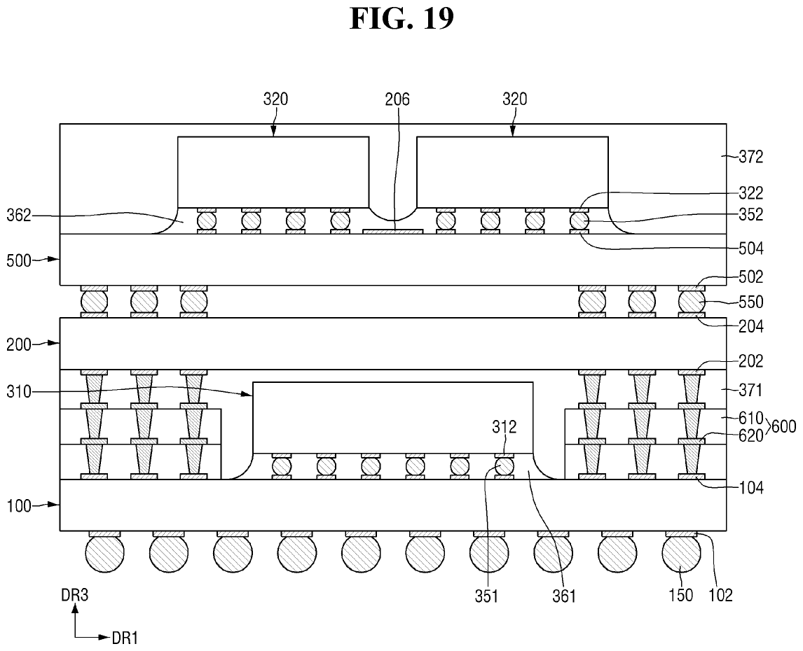

FIG. 19 is a diagram that illustrates a semiconductor package according to some embodiments. For convenience of description, the following description is based on differences from those set forth above with reference to FIGS. 1 to 18.

Referring to FIG. 19, the semiconductor package according to some embodiments may further include a connective substrate 600 disposed between the first substrate 100 and the interposer 200. The connective substrate 600 may border and at least partially surround the first semiconductor chip 310. The connective substrate 600 may include a connective insulating layer 610 and a connective wiring 620.

The connecting insulating layer 610 may be disposed on the substrate 100. The connective insulating layer 610 may have a stack structure of layers stacked in the third direction DR3. The connective insulating layer 610 may include an insulating material.

The connecting wiring 620 may include a stack of a plurality of wiring layers disposed within the connective insulating layer 610 and positioned at different levels, and conductive vias disposed within the redistribution insulating layer 410 and extending in the third direction DR3 to connect the plurality of wiring layers to each other. The connective wiring 620 may include a conductive material. The connective wiring 620 may be electrically connected to the second substrate pad 104 of the first substrate 100 and the first interposer pad 202 of the interposer 200.

Although embodiments of the inventive concept have been described with reference to the accompanying drawings, the inventive concept is not limited to the above embodiments, but may be implemented in various different forms. A person skilled in the art may appreciate that embodiments of the inventive concept may be practiced in other concrete forms without changing the technical spirit or essential characteristics of the inventive concept. Therefore, it should be appreciated that the embodiments as described above is not restrictive but illustrative in all respects.

What is claimed is:

1. A semiconductor package comprising:
a substrate;
a substrate pad on the substrate;
a first semiconductor chip and a second semiconductor chip on the substrate;
a connective terminal between the substrate pad and the first semiconductor chip and between the substrate pad and the second semiconductor chip;
a dummy pad on the substrate, and spaced apart from the substrate pad, wherein the dummy pad is between the first semiconductor chip and the second semiconductor chip; and
an underfill material layer interposed between the substrate and the first semiconductor chip and between the substrate and the second semiconductor chip,
wherein the dummy pad and the substrate pad comprise a same material.

2. The semiconductor package of claim 1, wherein a top face of the dummy pad is coplanar with a top face of the substrate pad.

3. The semiconductor package of claim 1, wherein the underfill material layer is on the dummy pad.

4. The semiconductor package of claim 1, wherein the first semiconductor chip and the second semiconductor chip are adjacent to each other in a first direction,
wherein the dummy pad has a first sidewall and a second sidewall opposite to each other in the first direction,
wherein the first semiconductor chip has a third sidewall,
wherein the second semiconductor chip has a fourth sidewall facing the third sidewall,
wherein the first sidewall of the dummy pad is aligned with the third sidewall of the first semiconductor chip in a vertical direction or is under the first semiconductor chip,
wherein the second sidewall of the dummy pad is aligned with the fourth sidewall of the first semiconductor chip in the vertical direction or is under the second semiconductor chip.

5. The semiconductor package of claim 1, wherein the first semiconductor chip and the second semiconductor chip are adjacent to each other in a first direction,
wherein the dummy pad includes a first dummy pad and a second dummy pad adjacent to each other in the first direction,
wherein the first dummy pad includes a first sidewall adjacent to the first semiconductor chip,
wherein the second dummy pad includes a second sidewall adjacent to the second semiconductor chip,
wherein the first semiconductor chip includes a third sidewall,
wherein the second semiconductor chip includes a fourth sidewall facing the third sidewall of the first semiconductor chip,
wherein the first sidewall of the first dummy pad is aligned with the third sidewall of the first semiconductor chip in a vertical direction or is under the first semiconductor chip,
wherein the second sidewall of the first dummy pad is aligned with the fourth sidewall of the second semiconductor chip in the vertical direction or is under the second semiconductor chip.

6. The semiconductor package of claim 5, wherein the dummy pad further includes a third dummy pad between the first dummy pad and the second dummy pad.

7. The semiconductor package of claim 1, wherein the first semiconductor chip and the second semiconductor chip are adjacent to each other in the first direction,
wherein a spacing in the first direction between the first semiconductor chip and the second semiconductor chip is smaller than or equal to a width in the first direction of the dummy pad.

8. The semiconductor package of claim 1, wherein the substrate includes a redistribution insulating layer and a redistribution pattern in the redistribution insulating layer.

9. The semiconductor package of claim 1, wherein the substrate includes:
a base layer;
a wiring insulating layer on the base layer;
a wiring pattern in the wiring insulating layer;
a through electrode extending through the base layer and electrically connected to the wiring pattern.

10. A semiconductor package comprising:
a substrate;
a substrate pad on the substrate;
a first semiconductor chip and a second semiconductor chip on the substrate and adjacent to each other;
a connective terminal between the substrate pad and the first semiconductor chip and between the substrate pad and the second semiconductor chip;
a dummy pad on the substrate and spaced apart from the substrate pad, wherein the dummy pad is between the first semiconductor chip and the second semiconductor chip; and
an underfill material layer interposed between the substrate and the first semiconductor chip and between the substrate and the second semiconductor chip, wherein the underfill material layer extends along the dummy pad,
wherein in a plan view of the semiconductor package, the dummy pad overlaps at least a portion of the first semiconductor chip and at least a portion of the second semiconductor chip.

11. The semiconductor package of claim 10, wherein in a plan view of the semiconductor package, the dummy pad has a rectangular, circular, polygonal or oval shape.

12. The semiconductor package of claim 10, wherein the dummy pad includes:
a first dummy pad overlapping at least a portion of the first semiconductor chip in a plan view of the package; and
a second dummy pad overlapping at least a portion of the second semiconductor chip in the plan view.

13. The semiconductor package of claim 12, wherein the dummy pad further includes a third dummy pad between the first dummy pad and the second dummy pad.

14. The semiconductor package of claim 10, wherein the first semiconductor chip includes a first chip pad,
wherein the second semiconductor chip includes a second chip pad,
wherein the connective terminal is in contact with the first chip pad of the first semiconductor chip and the substrate pad of the substrate, and is in contact with the second chip pad of the second semiconductor chip and the substrate pad on the substrate.

15. The semiconductor package of claim 10, wherein a thickness of the dummy pad on the substrate is substantially equal to a thickness of the substrate pad on the substrate.

16. The semiconductor package of claim 10, wherein the dummy pad and the substrate pad comprise a same material.

17. The semiconductor package of claim 10, wherein the first semiconductor chip and the second semiconductor chip are adjacent to each other in a first direction,
wherein the dummy pad includes dummy pads between the first semiconductor chip and the second semiconductor chip and arranged along a second direction intersecting the first direction.

18. A semiconductor package comprising:
a substrate including a first face and a second face opposite to each other in a first direction;
a substrate pad on the second face of the substrate;
a first semiconductor chip and a second semiconductor chip on the second face of the substrate and adjacent to each other in the first direction;
a third semiconductor chip on the second face of the substrate and adjacent to the first semiconductor chip in a second direction intersecting the first direction;
a connective terminal configured to electrically connect a chip pad of each of the first to third semiconductor chip to the substrate pad;
a dummy pad on the second face of the substrate, the dummy pad being between the first semiconductor chip and the second semiconductor chip and between the first semiconductor chip and the third semiconductor chip; and
an underfill material layer in a space between the substrate and the first semiconductor chip, in a space between the substrate and the second semiconductor chip, and in a space between the substrate and the third semiconductor chip, wherein the underfill material layer is on the dummy pad,
wherein the dummy pad and the substrate pad comprise a same material.

19. The semiconductor package of claim 18, wherein the dummy pad includes:
a first dummy pad overlapping at least a portion of the first semiconductor chip and at least a portion of the second semiconductor chip in the first direction; and
a second dummy pad overlapping at least a portion of the first semiconductor chip and at least a portion of the third semiconductor chip in the first direction.

20. The semiconductor package of claim 18, wherein a thickness of the dummy pad on the substrate is substantially equal to a thickness of the substrate pad on the substrate.
